(19) United States
(12) Patent Application Publication
(10) Pub. No.: US 2009/0321761 A1
(43) Pub. Date: Dec. 31, 2009

(54) COATING FOR CONVERTING OPTICAL SPECTRUM AND LED CHIP PACKAGE MODULE USING THE SAME

(75) Inventors: Chao-Chin Wu, Taipei City (TW); Kwang-Chao Huang, Taoyuan City (TW); Wei-Chun Yang, Taipei City (TW)

Correspondence Address: NIKOLAI & MERSEREAU, P.A., 900 SECOND AVENUE SOUTH, SUITE 820, MINNEAPOLIS, MN, 55402, US

(73) Assignee: PARAGON TECHNOLOGIES CO., LTD., Guishan Shiang (TW)

(21) Appl. No.: 12/241,533

(22) Filed: Sep. 30, 2008

(30) Foreign Application Priority Data
Jun. 30, 2008 (TW) 97124597

(51) Int. Cl. H01L 33/00; G02F 1/361

(52) U.S. Cl. 257/98; 252/582; 252/584; 257/E33.061

(57) ABSTRACT

A coating for converting optical spectrum includes: a transparent colloid layer and an emitter material unit. The emitter material unit is used to convert one part of a short-wavelength band of a light source into a long-wavelength band. The emitter material unit has at least one first emitter body and at least one second emitter body both mixed with the transparent colloid layer, the at least one first emitter body is an inorganic silicate compound, and the at least one second emitter body is aan organic dye. Hence, the color rendering index (CRI) and the range of color temperature of white light generated by an LED chip package module using the coating are increased according to the function of the emitter material unit for converting one part of a short-wavelength band of a light source into a long-wavelength band.

### BACKGROUND OF THE INVENTION

1. Field of the Invention

The present invention relates to a coating and an LED chip package module using the same, and particularly relates to a coating for converting optical spectrum and an LED chip package module using the same.

2. Description of Related Art

LED (light Emitting diode) is a semiconductor component. It has a small size, and its advantage is that It can efficiently generate light having emission peak at different wavelength in the visible region corresponding to a monochromatic color. If light of different wavelengths emitted by many LEDs is mixed, a white light source can be obtained.

A first type of white LED has three separated wavelength peaks for generating white light. The primary principle of the white LED with three separated wavelength peaks for generating white light is the following: three LEDs such as a red LED, a green LED and a blue LED, generating light of three separated wavelength peaks in the visible range can be combined in order to generate white light. Because each LED is a light source with a distinct wavelength distribution range corresponding to a monochromatic color, the white light source resulting from mixing the three separated wavelength peaks is always non-uniform due to different decay rate for each color.

A second type of white LED has two separated wavelength peaks for generating white light. The primary principle of the white LED with two separated wavelength peaks for generating white light is the following: a blue LED is combined with a yellow inorganic phosphor. The blue LED generates blue light with wavelength distribution lying between 440 nm˜490 nm, and the blue light is emitted onto the yellow inorganic phosphor to generate yellow light. Hence, the blue light can mix with the yellow light in order to generate white light. However, the light-emitting efficiency of the white LED with two separated wavelength peaks is low. In addition, the white light is generated by mixing only two separated wavelength peaks such as blue light and yellow light, so the color rendering index (CRI) and the range of the color temperature of the second type of white LED are worse than the first type of white LED.

It is a priority for engineers to design a semiconductor light-emitting device with high color rendering index (CRI). However, the first type of white LED using many LEDs (such as red LED, green LED, blue LED) with separated wavelength peaks to generate white light can only obtain a color rendering index of about 80, and the generated white light is non-uniform due to different decay rate. In addition, the second type of white LED using only two separated wavelength peaks such as blue light and yellow light to generate white light can only obtain a color rendering index of about 50˜80, so the color rendering index (CRI) and the range of the color temperature of the second type of white LED are not good enough.

### SUMMARY OF THE INVENTION

One particular aspect of the present invention is to provide a coating for converting optical spectrum and an LED chip package module using the same. The present invention mixes an emitter material unit for converting one part of a short-wavelength band of a blue light source into a long-wavelength band with a transparent colloid layer in order to obtain a coating for converting optical spectrum. Hence, the color rendering index (CRI) and the range of color temperature of white light generated by the LED chip package module are improved according to the function of the emitter material unit for converting one part of a short-wavelength band of a blue light source into a long-wavelength band.

In order to achieve the above-mentioned aspects, the present invention provides a coating for converting optical spectrum, including: a transparent colloid layer and an emitter material unit. The emitter material unit is used to convert one part of a short-wavelength band of a blue light source into a long-wavelength band. The emitter material unit has at least one first emitter body and at least one second emitter body mixed with the transparent colloid layer, the first emitter body is an inorganic silicate compound, and the second emitter body is a fluorescence.

Hence, the present invention has following advantages:

1. When a blue LED mates with the coating for converting optical spectrum, the emitter material unit can be used to convert one part of a short-wavelength band of a blue light source into a long-wavelength band. Therefore, the color rendering index (CRI) can be increased to 85.

2. When the coating is in a solid state, the coating can be indirectly disposed on the LED chip package module via the adhesive glue. For example, the coating is indirectly disposed on the LED chip package module by pasting the adhesive glue between the coating and the LED chip package module.

3. When the coating is in a liquid state, the liquid coating can be directly formed on the LED chip package module by an external forming device, and the liquid coating becomes the solid coating disposed on the LED chip package module after cooling the liquid coating.

4. Because the coating can be directly disposed on the LED chip package module. Hence, an emitter colloid body of the prior art can be replaced by the coating of the present invention.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a lateral, schematic view of a coating for converting optical spectrum of the present invention;

FIG. 2 is a lateral, schematic view of an LED chip package module using a coating for converting optical spectrum according to the first embodiment of the present invention;

FIG. 3 is a lateral, schematic view of an LED chip package module using a coating for converting optical spectrum according to the second embodiment of the present invention;

FIG. 4 is a lateral, schematic view of an LED chip package module using a coating for converting optical spectrum according to the third embodiment of the present invention; and

FIG. 5 is a graph of emission spectrum of a coating for converting optical spectrum of the present invention mated with a blue LED.

### DETAILED DESCRIPTION OF PREFERRED EMBODIMENTS

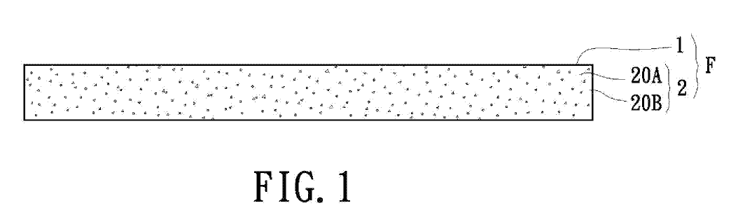

Referring to FIG. 1, the present invention provides a coating F for converting optical spectrum, including: a transparent colloid layer 1 and an emitter material unit 2. The emitter material unit 2 is used to convert one part of a short-wavelength band of a predetermined light source into a long-wavelength band. In the present invention, the predetermined light source can be a blue light source. However, the blue LED is just an example and it does not use to limit the type of the LED of the present invention.

Moreover, the transparent colloid layer 1 can be composed of any transparent colloid material. For example, the transparent colloid layer 1 can be composed of epoxy or silicon; alternatively the transparent colloid layer 1 can be composed of a mixture formed by mixing epoxy and silicon.

Furthermore, the emitter material unit 2 has at least one first emitter body 20A and at least one second emitter body 20B mixed with the transparent colloid layer 1 together. The first emitter body 20A can be an inorganic silicate compound, and the second emitter body 20B can be a fluorescence.

With regards to the first emitter body 20A, the inorganic silicate compound can be selected from the group consisting of (Me_{1-x-y}EuₓRe_{y})₈Mg_{z}(SiO₄)ₘClₙ, (Me₁₋ₓEuₓ)ReS and (Ca_{1-x-y}SrₓBa_{y})₅(PO₄)₃Cl:Eu²⁺Gd²⁺, the Me is selected from the group consisting of calcium, strontium and barium, the Re is selected from the group consisting of dysprosium, europium, thulium, magnesium, zinc and samarium, and 0<x≦0.8, 0≦y≦0.4, 0≦z≦1.0, 1.0≦m≦6.0 and 0.1≦n≦3.0. However, above-mentioned definition for the first emitter body 20A is just an example. The present invention can use any type of inorganic silicate compound according to different requirements for color rendering index (CRI) and color.

With regards to the second emitter body 20B, the organic dye can be composed of carbon, hydrogen, nitrogen, oxygen and sulfur. With regards to the best mold of the present invention, the molecular formula of the organic dye is C₂₆H₂₆N₂O₂S. In addition, in the organic dye, the proportion of carbon is 72.5%, the proportion of hydrogen is 6.1%, the proportion of nitrogen is 6.5%, the proportion of oxygen is 7.4%, and the proportion of sulfur is 7.5%. Moreover, the chemical structure-formula of the organic dye is:

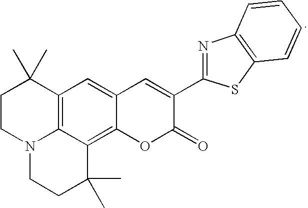

With regards. to the ratio of the transparent colloid layer 1, the first emitter body 20A and the second emitter body 20B, the present invention discloses as the following:

1. The range of the proportion of the transparent colloid layer 1 in the coating F is 0.1˜99.895%.

2. The range of the proportion of the first emitter body 20A in the coating F is 0.1˜5%.

3. The range of the proportion of the second emitter body 20B in the coating F is 0.001˜5%.

In addition, the best ratio of the transparent colloid layer 1, the first emitter body 20A and the second emitter body 20B is that: the transparent colloid layer 1 (such as silicon) occupies 95%, the first emitter body 20A (such as inorganic silicate compound) occupy 4.99%, and the second emitter body 20B (such as organic dye) occupy 0.01%.

Furthermore, the present invention can mix the transparent colloid layer 1 with the second emitter body 20B only. The emitter material unit 2 with merely the second emitter body 20B can achieve the function of converting one part of a short-wavelength band of a predetermined light source into a long-wavelength band. The emitter body 20B can be composed of organic dyes.

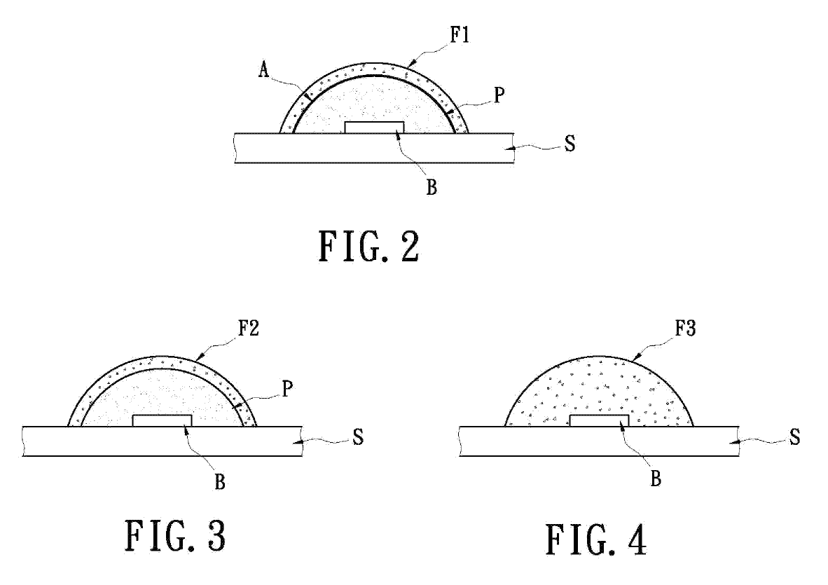

Referring to FIG. 2, the first embodiment provides an LED chip package module including: a substrate S, a blue LED B electrically disposed on the substrate S, and an emitter colloid body P covering the blue LED B. The emitter colloid body P is made by mixing emitter powders with a transparent colloid body. Hence, the emitter colloid body P has two functions both as package layer and as emitter layer. In addition, the LED chip package module has a coating F1 that is in a solid state, so the coating F1 can be disposed on the emitter colloid body P via adhesive glue A. For example, the coating is indirectly disposed on the LED chip package module by pasting the adhesive glue A between the coating and the LED chip package module.

Referring to FIG. 3, the second embodiment provides an LED chip package module including: a substrate S, a blue LED B electrically disposed on the substrate S, and an emitter colloid body P covering the blue LED B. In addition, the LED chip package module has a coating F2 that can be disposed on the emitter colloid body P by a forming method. The forming method can be a dipping method, a coating method, a printing method, or a spraying method. However, above-mentioned forming methods are just examples and they do not use to limit the present invention.

Furthermore, the coating (F1 or F2) can be directly or indirectly disposed on the emitter colloid body P according to the first and the second embodiment. For example, when the coating F1 is in a solid state, the coating F1 can be indirectly disposed on the emitter colloid body P via the adhesive glue A (For example, the coating is indirectly disposed on the LED chip package module by pasting the adhesive glue A between the coating and the LED chip package module); When a coating is in a liquid state, the liquid coating can be directly formed on the emitter colloid body P by an external forming device, and the liquid coating becomes the solid coating F2 disposed on the emitter colloid body P after cooling the liquid coating.

Referring to FIG. 4, the third embodiment provides an LED chip package module including: a substrate S and a blue LED B electrically disposed on the substrate S. The LED chip package module has a coating F3 directly disposed on the blue LED B. Hence, the emitter colloid body P in above-mentioned embodiments can be replaced by the coating F3 in the third embodiment.

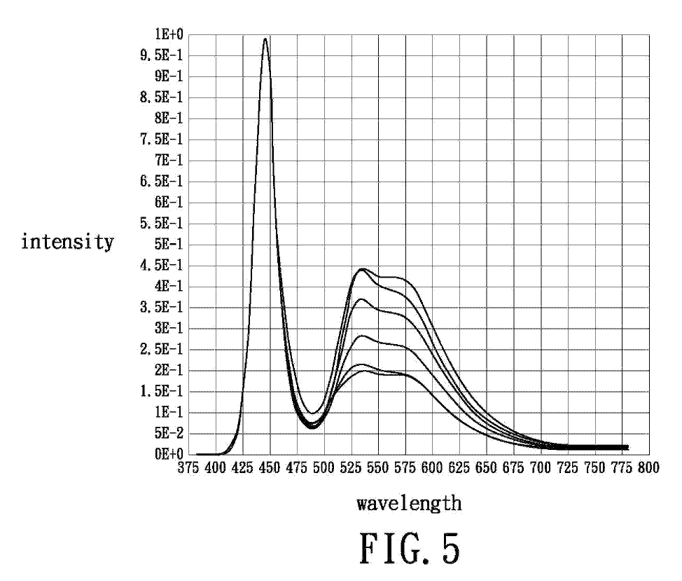

FIG. 5 shows a graph of emission spectrum of a coating for converting optical spectrum of the present invention mated with a blue LED. The present invention uses the coating that can convert one part of a short-wavelength band of a predetermined light source into a long-wavelength band, so the color rendering index (CRI) can be increased. In other words, the radiant intensity of a long-wavelength band about 550 nm˜700 nm generated by a blue LED mating with emitter powders can be effectively increased due to the usage of the coating of the present invention. The lower curve in FIG. 5 is the prior radiant intensity of wavelength band about 500 nm˜700 nm. When adding the first emitter body 20A with different ratio and the second emitter body 20B with different ratio into the transparent colloid layer 1, the radiant intensity of the wavelength band about 500 nm˜700 nm is increased. Especially, when adding the second emitter body 20B into the transparent colloid layer 1, the radiant intensity of the wavelength band about 500 nm˜700 nm is increased obviously.

However, the match of the blue LED and the coating for converting optical spectrum is just an example. Any method and LED package module for converting one part of a short-wavelength band of a predetermined light source into a long-wavelength band is protected in the present invention.

In conclusion, the present invention discloses mixing an emitter material unit for converting one part of a short-wavelength band of a light source (such as blue light source) into a long-wavelength band with a transparent colloid layer in order to obtain a coating for converting optical spectrum. Hence, the color rendering index (CRI) and the range of color temperature of white light generated by the LED chip package module are increased according to the function of the emitter material unit for converting one part of a short-wavelength band of a light source (such as blue light source) into a long-wavelength band.

Hence, the present invention has following advantages:

1. When a blue LED mates with the coating for converting optical spectrum, the emitter material unit can be used to convert one part of a short-wavelength band of a blue light source into a long-wavelength band. Therefore, the color rendering index (CRI) can be increased to 85.

2. When the coating is in a solid state, the coating can be indirectly disposed on the LED chip package module via the adhesive glue A. For example, the coating is indirectly disposed on the LED chip package module by pasting the adhesive glue A between the coating and the LED chip package module

3. When the coating is in a liquid state, the liquid coating can be directly formed on the LED chip package module by an external forming device, and the liquid coating becomes the solid coating disposed on the LED chip package module after cooling the liquid coating.

4. Because the coating can be directly disposed on the LED chip package module. Hence, an emitter colloid body of the prior art can be replaced by the coating of the present invention.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

1. A coating for converting optical spectrum, comprising:
a transparent colloid layer; and
an emitter material unit for converting one part of a short-wavelength band of a predetermined light source into a long-wavelength band, wherein the emitter material unit has at least one first emitter body and at least one second emitter body mixed with the transparent colloid layer, the at least one first emitter body being an inorganic silicate compound, and the at least one second emitter body being an organic dye.

2. The coating as claimed in claim 1, wherein the predetermined light source is a blue light source.

3. The coating as claimed in claim 1, wherein the transparent colloid layer is composed of epoxy, silicon, or a mixture formed by mixing epoxy and silicon.

4. The coating as claimed in claim 1, wherein the inorganic silicate compound is selected from the group consisting of (Me_{1-x-y}EuₓRe_{y})₈Mgₓ(SiO₄)ₘClₙ, (Me₁₋ₓEuₓ)ReS and (Ca_{1-x-y}SrₓBa_{y})₅(PO₄)₃Cl:Eu²⁺Gd²⁺, the Me is selected from the group consisting of calcium, strontium and barium, the Re is selected from the group consisting of dysprosium, europium, thulium, magnesium, zinc and samarium, and 0<x≦0.8, 0≦y≦0.4, 0≦z≦1.0, 1.0≦m≦6.0 and 0.1≦n≦3.0.

5. The coating as claimed in claim 1, wherein the organic dye is composed of carbon, hydrogen, nitrogen, oxygen and sulfur.

6. The coating as claimed in claim 5, wherein in the organic dye, the proportion of carbon is 72.5%, the proportion of hydrogen is 6.1%, the proportion of nitrogen is 6.5%, the proportion of oxygen is 7.4%, and the proportion of sulfur is 7.5%.

7. The coating as claimed in claim 1, wherein the molecular formula of the organic dye is C₂₆H₂₆N₂O₂S.

8. The coating as claimed in claim 1, wherein the chemical structure-formula of the organic dye is:

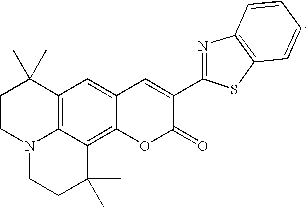

9. The coating as claimed in claim 1, wherein the range of the proportion of the transparent colloid layer in the coating is 0.1˜99.895%.

10. The coating as claimed in claim 1, wherein the range of the proportion of the at least one first emitter body in the coating is 0.1˜5%.

11. The coating as claimed in claim 1, wherein the range of the proportion of the at least one second emitter body in the coating is 0.001˜5%.

12. An LED chip package module using the coating for converting optical spectrum as claimed in claim 1, comprising: a substrate, an LED electrically disposed on the substrate, and an emitter colloid body covering the LED, wherein the coating is disposed on the emitter colloid body.

13. The LED chip package module as claimed in claim 12, wherein the coating is in a solid state, so the coating is disposed on the emitter colloid body via adhesive glue.

14. The LED chip package module as claimed in claim 12, wherein the coating is disposed on the emitter colloid body by a forming method.

15. The LED chip package module as claimed in claim 14, wherein the forming method is a dipping method, a coating method, a printing method, or a spraying method.

16. An LED chip package module using the coating for converting optical spectrum as claimed in claim 1, comprising: a substrate and a blue LED electrically disposed on the substrate, wherein the coating is disposed on the blue LED.

17. A coating for converting optical spectrum, comprising:
a transparent colloid layer; and
an emitter material unit for converting one part of a short-wavelength band of a predetermined light source into a long-wavelength band, wherein the emitter material unit has at least one emitter body mixed with the transparent colloid layer, and the at least one emitter body is an organic dye.

18. The coating as claimed in claim 17, wherein the predetermined light source is a blue light source.

19. The coating as claimed in claim 17, wherein the transparent colloid layer is composed of epoxy, silicon, or a mixture formed by mixing epoxy and silicon.

20. The coating as claimed in claim 17, wherein the chemical structure-formula of the organic dye is: [chemical structure]
